(19) United States
(12) Patent Application Publication
(10) Pub. No.: US 2006/0286703 A1
(43) Pub. Date: Dec. 21, 2006

(54) Thin film transistor array panel and liquid crystal display including the same

(76) Inventors: Yoon-Sung Um, Yongin-si (KR); Hyun-Wuk Kim, Yongin-si (KR); Jae-Jin Lyu, Gwangiu-si (KR)

Correspondence Address: F. CHAU & ASSOCIATES, LLC, 130 WOODBURY ROAD, WOODBURY, NY, 11797, US

(21) Appl. No.: 11/440,789

(22) Filed: May 25, 2006

(30) Foreign Application Priority Data
May 25, 2005 (KR) 2005-0044111

(51) Int. Cl. H01L 21/00; H01L 33/00

(52) U.S. Cl. 438/30; 257/88

(57) ABSTRACT

A thin film transistor array includes first and second gate lines and a storage electrode line with a storage electrode formed on a substrate, where a gate insulating layer covers the gate and the storage electrode lines, a data line crossing the first and second gate lines in an insulating manner and a conductor are formed on the gate insulating layer, a passivation layer covers the data line and the conductor, and a pixel electrode is formed on the passivation layer with first and second sub-pixel electrodes connected to the first and second gate lines, respectively, the conductor is connected to the first sub-pixel electrode, and overlaps the storage electrode, and as the second sub-pixel electrode overlaps the conductor overlapping the storage electrode, connection capacitors of the first and second sub-pixel electrodes are formed without deteriorating the aperture ratio, and the charging up is induced at the first sub-pixel electrode when the second sub-pixel electrode is inverted in polarity.

### CROSS-REFERENCE TO RELATED APPLICATION

This application claims foreign priority under 35 U.S.C. § 119 to Korean Patent Application No. 2005-0044111, filed on May 25, 2005 in the Korean Intellectual Property Office, the contents of which are herein incorporated by reference in their entirety.

### BACKGROUND OF THE INVENTION

(a) Field of the Invention

The present disclosure relates to liquid crystal displays, and more particularly relates to liquid crystal displays having thin film transistor array panels.

(b) Description of the Related Art

A liquid crystal display (“LCD”) is one of the most extensively used types of flat panel display devices. An LCD includes two display panels having field-generating electrodes mounted thereon, such as pixel and common electrodes, and a liquid crystal layer sandwiched therebetween. The LCD generates an electric field in the liquid crystal layer by applying voltages to the field-generating electrodes, and aligns the liquid crystal molecules of the liquid crystal layer to control the polarization of light incident thereto, thereby displaying desired images.

A vertically aligned (“VA”) mode LCD has been spotlighted, in which the directions of liquid crystal molecules are aligned vertical to the upper and lower panels with no application of an electric field, as it gives a high contrast ratio and wide reference viewing angle. The reference viewing angle refers to a viewing angle with a contrast ratio of 1:10, or an inter-gray luminance inversion limit angle.

Unfortunately, the VA mode LCD has poor visibility at the lateral side thereof, compared to the visibility at its front side. For example, in the case of a patterned vertically aligned (“PVA”) mode LCD having cutouts, the luminance thereof is heightened toward the lateral side thereof, and in a serious case, the luminance difference between the high grays is eradicated so that the display image may appear to be distorted.

In order to enhance the lateral side visibility, it has been proposed that a pixel electrode should be divided into two sub-pixel electrodes, which are capacitor-combined with each other. A voltage is directly applied to one of the sub-pixel electrodes, and a voltage drop occurs at the other sub-pixel electrode due to the capacitor combination. In this way, the two sub-pixel electrodes are differentiated in voltage from each other with different light transmittances.

With such a method, the transmittances of the two sub-pixel electrodes cannot be correctly controlled to the desired level. The light transmittance is different for respective colors. However, the voltages cannot be separately adjusted with respect to the respective colors. In addition, the aperture ratio is deteriorated due to the addition of a conductor for a capacitor combination, and the light transmittance is reduced due to the capacitor combination-induced voltage drop.

### SUMMARY OF THE INVENTION

An embodiment of the present disclosure provides a liquid crystal display that has enhanced visibility with no loss in the aperture ratio.

According to an embodiment of the present disclosure, a liquid crystal display is provided in which a pixel electrode is divided into two sub-pixel electrodes that are capacitor-combined with each other such that they receive different potentials via the respective switching elements, and a capacitor combination is formed on a storage capacitor of one of the sub-pixel electrodes to enhance the visibility without deteriorating the aperture ratio.

According to an embodiment of the present disclosure, a thin film transistor array panel includes a substrate, a first signal line formed on the substrate, second and third signal lines crossing the first signal line, a first thin film transistor connected to the first and second signal lines, a second thin film transistor connected to the first and third signal lines, a pixel electrode having a first sub-pixel electrode connected to the first thin film transistor and a second sub-pixel electrode connected to the second thin film transistor, a conductor connected to the first sub-pixel electrode or the first thin film transistor and overlapping the second sub-pixel electrode, and a storage electrode overlapping the conductor.

The storage electrode and the second sub-pixel electrode may be placed around the conductor opposite to each other. The thin film transistor array panel may further include a first insulating layer disposed between the storage electrode and the conductor, and a second insulating layer disposed between the conductor and the sub-pixel electrodes. The second insulating layer may include a lower layer portion based on an inorganic insulating material and an upper layer portion based on an organic insulating material. It is preferable that the conductor and the second sub-pixel electrode overlap each other while interposing the lower layer portion of the second insulating layer.

The first sub-pixel electrode may be divided into separate portions while interposing the second sub-pixel electrode. The thin film transistor array panel may further include a shielding electrode overlapping the data line.

The first and second sub-pixel electrodes may be inverted with the same polarity. The data voltages applied to the first and second sub-pixel electrodes may be differentiated in dimension from each other.

According to another embodiment of the present disclosure, a liquid crystal display includes a substrate, a first signal line formed on the substrate, second and third signal lines crossing the first signal line, a first thin film transistor connected to the first and second signal lines, a second thin film transistor connected to the first and third signal lines, a pixel electrode having a first sub-pixel electrode connected to the first thin film transistor and a second sub-pixel electrode connected to the second thin film transistor, a conductor connected to the first sub-pixel electrode or the first thin film transistor and overlapping the second sub-pixel electrode, a storage electrode overlapping the conductor, and a common electrode facing the first and second sub-pixel electrodes.

At least one of the first and second sub-pixel electrodes and the common electrode may have cutouts arranged in an alternate manner. A gap between the first and second sub-pixel electrodes and the cutout of the common electrode may be arranged in an alternate manner.

### BRIEF DESCRIPTION OF THE DRAWINGS

The present invention will become more apparent by describing exemplary embodiments thereof in detail with reference to the accompanying drawings, in which:

FIGS. 1A to 1C are block diagrams of a liquid crystal display (“LCD”) according to an embodiment of the present disclosure;

FIG. 2 is an equivalent circuit diagram of a pixel of an LCD according to an embodiment of the present disclosure;

FIG. 3 is an equivalent circuit diagram of a sub-pixel of an LCD according to an embodiment of the present disclosure;

FIG. 4 is a plan view of a thin film transistor array panel for an LCD according to an embodiment of the present disclosure;

FIG. 5 is a plan view of a common electrode panel for an LCD according to an embodiment of the present disclosure;

FIG. 6 is a plan view of an LCD with the two panels shown in FIGS. 4 and 5;

FIGS. 7A and 7B are cross sectional views of the LCD taken along the VIIa-VIIa line and the VIIb-VIIb′-VIIb″ line, respectively, of FIG. 6;

FIG. 8 is a plan view of an LCD according to another embodiment of the present disclosure;

FIG. 9 is a cross-sectional view of the LCD taken along the IX-IX line of FIG. 8;

FIG. 10 is a plan view of an LCD according to another embodiment of the present disclosure;

FIG. 11 is a cross-sectional view of the LCD taken along the XI-XI line of FIG. 10;

FIG. 12 is a plan view of an LCD according to another embodiment of the present disclosure; and

FIG. 13 is a cross-sectional view of the LCD taken along the XIII-XIII line of FIG. 12.

### DETAILED DESCRIPTION OF PREFERRED EMBODIMENTS

The present invention will be described more fully hereinafter with reference to the accompanying drawings, in which preferred embodiments of the invention are shown. The present invention may, however, be embodied in many different forms and should not be construed as limited to the exemplary embodiments set forth herein.

In the drawings, the thickness of layers, films, and regions may be exaggerated for clarity. Like reference numerals may refer to like elements throughout. It will be understood that when an element such as a layer, film, region or substrate is referred to as being “on” another element, it can be directly on the other element or intervening elements may also be present. In contrast, when an element is referred to as being “directly on” another element, there are no intervening elements present. Now, LCDs according to embodiments of the present disclosure will be specifically explained with reference to the accompanying drawings.

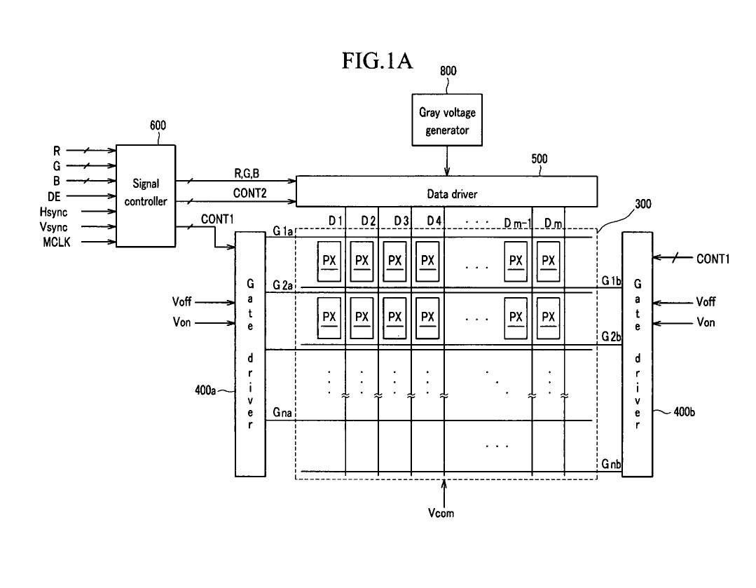

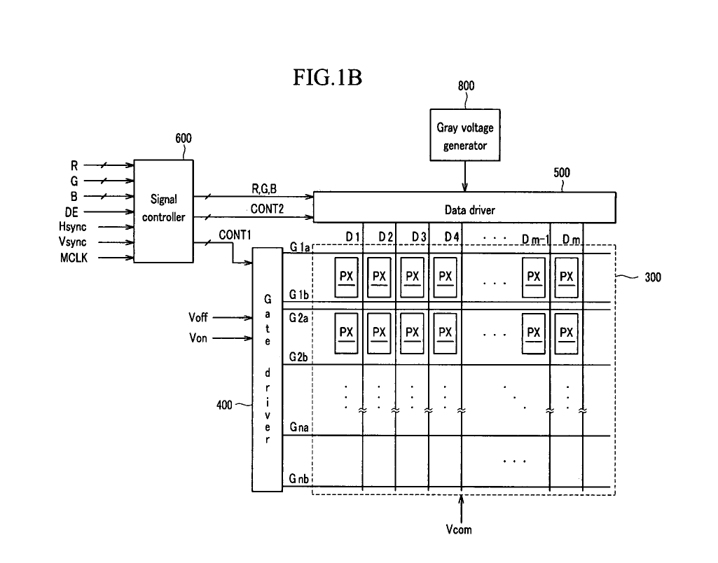

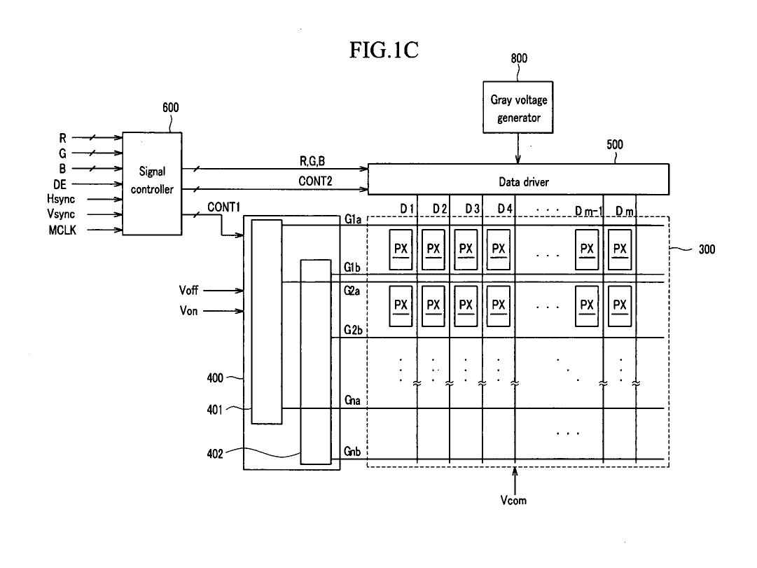

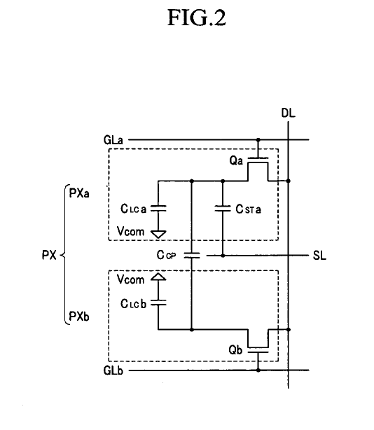

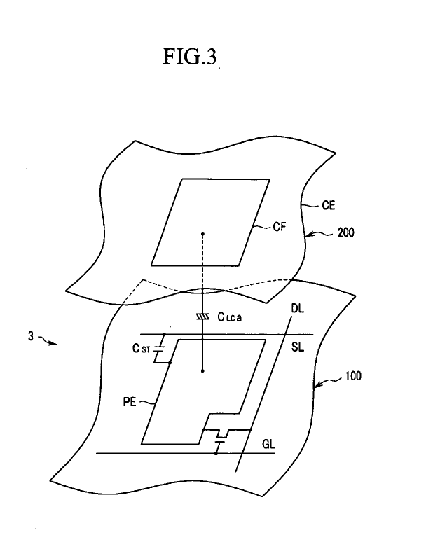

FIGS. 1A to 1C are block diagrams of an LCD according to an embodiment of the present disclosure, FIG. 2 is an equivalent circuit diagram of a pixel of an LCD according to an embodiment of the present disclosure, and FIG. 3 is an equivalent circuit diagram of a sub-pixel of an LCD according to an embodiment of the present disclosure.

As shown in FIGS. 1A to 1C, an LCD according to an embodiment of the present disclosure includes a liquid crystal panel assembly 300, a pair of gate drivers 400a and 400b or a single gate driver 400 connected to the liquid crystal panel assembly 300, a data driver 500 connected to the liquid crystal panel assembly 300, a gray voltage generator 800 connected to the data driver 500, and a signal controller 600 for controlling the drivers.

From the perspective of an equivalent circuit, the liquid crystal panel assembly 300 includes a plurality of display signal lines, and a plurality of pixels PX connected to those lines and arranged in the form of a matrix. By contrast, from the perspective of a structure shown in FIG. 3, the liquid crystal panel assembly 300 includes lower and upper panels 100 and 200 facing each other, and a liquid crystal layer 3 disposed between the two panels.

The display signal lines are provided on the lower panel 100, and include a plurality of gate lines G1a-Gnb for transmitting gate signals (also called “scanning signals”), and data lines D1-Dm for transmitting data signals. The gate lines G1a-Gnb extend in the direction of pixel rows parallel to each other, and the data lines D1-Dm extend in the direction of pixel columns parallel to each other.

FIG. 2 illustrates the display signal lines and an equivalent circuit of a pixel. The display signal lines include gate lines indicated by GLa and GLb, a data line indicated by DL, and a storage electrode line SL. The storage electrode line SL extends parallel to the gate lines GLa and GLb.

As shown in FIG. 2, each pixel PX has a pair of sub-pixels PXa and PXb, and a connection capacitor Ccp interconnecting the sub-pixels PXa and PXb. The respective sub-pixels PXa and PXb include switching elements Qa and Qb connected to the relevant gate lines GLa and GLb and the data line DL, and liquid crystal capacitors C_{Lca} and C_{LCb} connected to the switching elements Qa and Qb. One of the two sub-pixels PXa and PXb, that is, the first sub-pixel PXa, has a storage capacitor C_{STa} connected to the switching element Qa and the storage electrode line SL.

As shown in FIG. 3, the switching element of the respective sub-pixels PXa and PXb is formed with a thin film transistor provided at the lower panel 100. The switching element is a triode device with a control terminal connected to the gate line GL, an input terminal connected to the data line DL, and an output terminal connected to the liquid crystal capacitor C_{LC} and the storage capacitor CST.

The liquid crystal capacitor C_{LC} takes the sub-pixel electrode PE of the lower panel 100 and the common electrode CE of the upper panel 200 as two terminals, and the liquid crystal layer 3 disposed between the two electrodes PE and CE functions as a dielectric. The sub-pixel electrode PE is connected to the switching element, and the common electrode CE is formed on the entire surface of the upper panel 200 to receive a common voltage Vcom. Unlike the structure shown in FIG. 3, the common electrode CE may be provided at the lower panel 100, and in this case, at least one of the two electrodes PE and CE may be formed in the shape of a line or a bar.

The storage capacitor CST subsidiary to the liquid crystal capacitor C_{LC} is formed by overlapping the storage electrode line SL provided at the lower panel 100 with the pixel electrode PE while interposing an insulator, and a predetermined voltage such as a common voltage Vcom is applied to the storage electrode line SL. Alternatively, the storage capacitor C_{ST} may be formed by overlapping the sub-pixel electrode PE with the just previous gate line while interposing an insulator.

Meanwhile, in order to express colors, the respective pixels PX should intrinsically express one of the primary colors (spatial division), or alternately express the primary colors in a temporal order (time division) such that the desired colors can be perceived by the spatial and/or temporal sum of the primary colors. The primary colors include red, green, and blue colors. FIG. 3 shows an example of the spatial division where each pixel PX has a color filer CF expressing one of the primary colors at the region of the upper panel 200. Unlike with the structure shown in FIG. 3, the color filter CF may be formed over or under the sub-pixel electrode PE of the lower panel 100.

As shown in FIGS. 1A to 1C, the gate drivers 400a, 400b, and 400 are connected to the gate lines G1a-Gnb to apply gate signals to the gate lines G1a-Gnb. The gate signals are formed with combinations of gate on and off voltages Von and Voff from the outside. As shown in FIG. 1A, the gate drivers 400a and 400b as a pair are placed at the left and right sides of the liquid crystal panel assembly 300 and connected to the odd-numbered and the even-numbered gate lines G1a-Gnb, respectively. Alternatively, as shown in FIGS. 1B and 1C, one gate driver 400 is placed at a side of the liquid crystal panel assembly 300, and is connected to all the gate lines G1a-Gnb. As shown in FIG. 1C, two driving circuits 401 and 402 are built into the gate driver 400, and are connected to the odd-numbered and even-numbered gate lines G1a-Gnb, respectively.

A gray voltage generator 800 generates two sets of gray voltages (or reference gray voltage sets) related to the pixel light transmittance. The two gray voltage sets are independently given to the two sub-pixels PXa and PXb forming one pixel PX, and each gray voltage set includes a gray voltage having a positive value with respect to the common voltage Vcom and a gray voltage having a negative value with respect to the common voltage Vcom. Alternatively, only one (reference) gray voltage set may be generated instead of the two (reference) gray voltage sets.

The data driver 500 is connected to the data lines D1-Dm of the liquid crystal panel assembly 300 to select one of the two gray voltage sets from the gray voltage generator 800, and apply one gray voltage of the selected gray voltage set to the pixel PX as a data voltage. However, if the gray voltage generator 800 does not give all the gray voltages but only gives the reference gray voltage, the data driver 500 divides the reference gray voltage to generate gray voltages with respect to all the grays, and selects the data voltage from the generated gray voltages.

The gate driver 400 (or 400a and 400b) or the data driver 500 is directly mounted on the liquid crystal panel assembly 300 in the form of one or more driving integrated circuit chips, or is mounted on a flexible printed circuit film and attached to the liquid crystal panel assembly 300 in the form of a tape carrier package (“TCP”). By contrast, the gate driver 400 (or 400a and 400b) or the data driver 500 may be integrated on the liquid crystal panel assembly 300. The signal controller 600 controls the operation of the gate and data drivers 400 and 500.

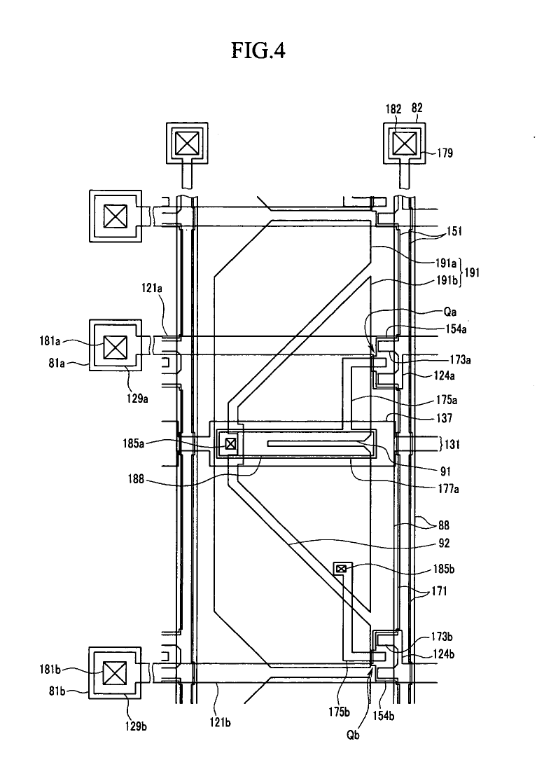

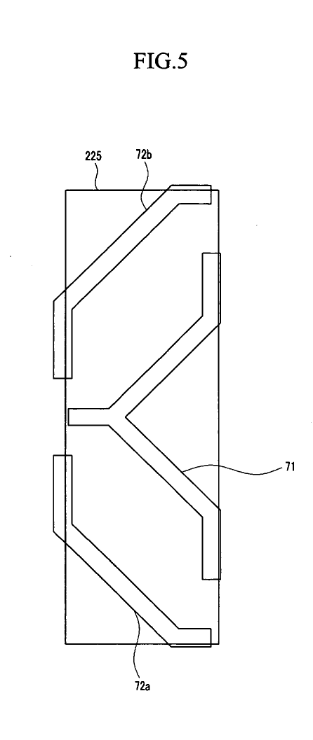

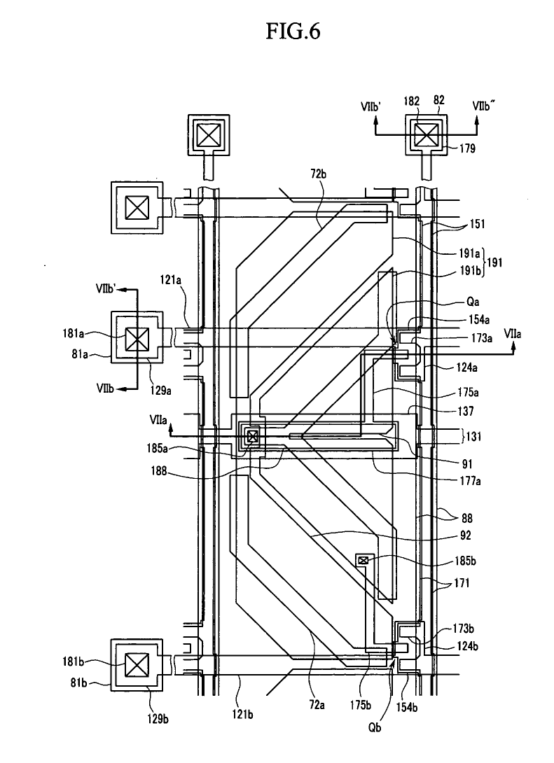

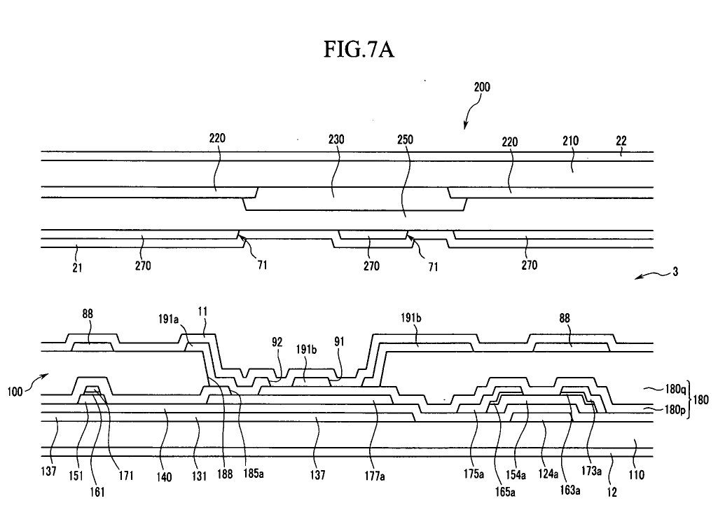

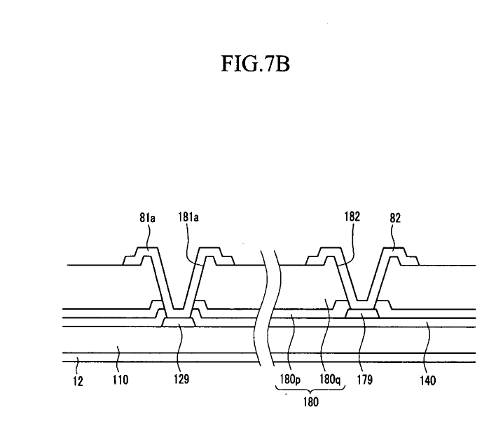

Now, the liquid crystal panel assembly will be specifically explained with reference to FIGS. 4 to 7B. FIG. 4 is a plan view of a thin film transistor array panel for an LCD according to an embodiment of the present disclosure, and FIG. 5 is a plan view of a common electrode panel for an LCD according to an embodiment of the present disclosure. FIG. 6 is a plan view of a liquid crystal panel assembly with the two panels shown in FIGS. 4 and 5, and FIGS. 7A and 7B are cross-sectional views of the liquid crystal panel assembly taken along the VIIa-VIIa line and the VIIb-VIIb′-VIIb″ line, respectively, of FIG. 6.

As shown in FIGS. 4 to 7B, the liquid crystal panel assembly according to an embodiment of the present disclosure includes a thin film transistor array panel 100 (previously called the lower panel), a common electrode panel 200 (previously called the upper panel), and a liquid crystal layer 3 disposed between the two panels 100 and 200.

First, the thin film transistor array panel 100 will be specifically explained with reference to FIGS. 4, 6, 7A, and 7B. A plurality of gate conductors with pairs of first and second gate lines 121a and 121b and a plurality of storage electrode lines 131 are formed on an insulating substrate 110 based on transparent glass or plastic. The first and second gate lines 121a and 121b extend horizontally to transmit gate signals, and are respectively located at upper and lower portions of FIGS. 4 and 6.

The first gate line 121a has a plurality of first gate electrodes 124a protruded downwards, and a left-side wide area end portion 129a to make a connection with another layer or an external driving circuit. The second gate line 121b has a plurality of second gate electrodes 124b protruded upwards, and a right-side wide area end portion 129b to make a connection with another layer or an external driving circuit.

Alternatively, the end portions 129a and 129b may be arranged at the same side. A gate driving circuit may be mounted on a flexible printed circuit film attached to the substrate 110, directly on the substrate 110, or integrated into the substrate 110. In the case that the gate driving circuit is integrated into the substrate 110, the gate lines 121a and 121b may extend to make a direct connection with the gate driving circuit.

The storage electrode line 131 receives a predetermined voltage, and extends in the horizontal direction. The respective storage electrode lines 131 are disposed between the first and second gate lines 121a and 121b, closer to first gate line 121a than to the second gate line 121b. The distance between the storage electrode line 131 and one of the two second gate lines 121b neighboring thereto is nearly the same as that between the storage electrode line 131 and the other second gate line 121b. The respective storage electrode lines 131 have storage electrodes 137 extended upwards and downwards. The shape and arrangement of the storage electrode lines 131 including the storage electrodes 137 may be altered in various forms.

The gate conductors 121a, 121b, and 131 are formed with an aluminum-based metallic material such as aluminum (Al) and an aluminum alloy, a silver-based metallic material such as silver (Ag) and a silver alloy, a copper-based metallic material such as copper (Cu) and a copper alloy, a molybdenum-based metallic material such as molybdenum (Mo) and a molybdenum alloy, chromium Cr, tantalum Ta, or titanium Ti. Alternatively, the gate conductors 121a, 121b, and 131 may have a multi-layered structure with two conductive layers differentiated in physical properties thereof. One of the conductive layers is formed with a low resistivity metallic material such as an aluminum-based metallic material, a silver-based metallic material, and/or a copper-based metallic material such that it can reduce the signal delay or voltage drop of the gate conductors 121a, 121b, and 131. By contrast, the other conductive layer is formed with a material having excellent physical, chemical, and electrical contact characteristics with respect to other materials like indium tin oxide ITO and indium zinc oxide IZO, such as a molybdenum-based metallic material, chromium, tantalum, and titanium. Good examples of such a combination are a structure with a chromium-based under layer and an aluminum (alloy)-based over layer, and a structure with an aluminum (alloy)-based under layer and a molybdenum (alloy)-based over layer. In addition, the gate conductors 121a, 121b, and 131 may be formed with various kinds of other metallic materials and conductors.

The lateral sides of the gate conductors 121a, 121b, and 131 are inclined with respect to the surface of the substrate 110, preferably at 30 to 80°. A gate insulating layer 140 is formed on the gate conductors 121a, 121b, and 131 with silicon nitride (SiNx) or silicon oxide (SiOx). A plurality of linear-shaped semiconductors 151 are formed on the gate insulating layer 140 with hydrogenated amorphous silicon (“a-Si”) or polysilicon. The linear-shaped semiconductors 151 extend in the vertical direction, and include pairs of first and second projections 154a and 154b projected toward the gate electrodes 124a and 124b, respectively. The linear-shaped semiconductors 151 are widened around the gate lines 121a and 121b and the storage electrode lines 131 such that they widely cover the latter.

A plurality of linear-shaped ohmic contacts 161 and a plurality of first island-shaped ohmic contacts 165a are formed on the linear-shaped semiconductors 151. The ohmic contacts 161 and 165a are formed with n+ hydrogenated amorphous silicon where n-type impurities such as phosphorous are doped at high concentration, or silicide. The linear-shaped ohmic contacts 161 have a plurality of first projections 163a, and the first projections 163a and the first island-shaped ohmic contacts 165a are arranged on the first projections 154a of the semiconductors 151 by pairs. The linear-shaped ohmic contacts 161 further have second projections placed on the second projections 154b of the semiconductors 151, and second island-shaped ohmic contacts are formed on the second projections 154b of the semiconductors 151 such that they face the second projections of the ohmic contacts 161. The lateral sides of the semiconductors 151 and the ohmic contacts 161 and 165a are inclined with respect to a surface of the substrate 110 at 30 to 80°.

Data conductors with a plurality of data lines 171 and a plurality of first and second drain electrodes 175a and 175b are formed on the ohmic contacts 161 and 165a and the gate insulating layer 140. The data lines 171 transmit data voltages, and extend vertically such that they cross the gate lines 121a and 121b and the storage electrode lines 131. The respective data lines 171 include a plurality of first and second source electrodes 173a and 173b extended toward the first and second gate electrodes 124a and 124b, respectively, and an end portion 179 enlarged in width to make a connection with another layer or an external driving circuit. A data driving circuit for generating data signals is mounted on a flexible printed circuit film attached to the substrate 110, directly on the substrate 110, or integrated into the substrate 110. In the case that the data driving circuit is integrated into the substrate 110, the data lines 171 may extend to make a direct connection with the data driving circuit.

The first and second drain electrodes 175a and 175b are separated from each other, and from the data lines 171. The first drain electrode 175a faces the first source electrode 173a around the first gate electrode 124a, and has a wide end portion forming a coupling electrode 177a and an opposite end portion having a bar-shape. The coupling electrode 177a overlaps the storage electrode 137, and the bar-shaped end portion is partially surrounded by the bent source electrode 173a. The second drain electrode 175b faces the second source electrode 173b around the second gate electrode 124b, and has a one-side wide end portion and an opposite-side bar-shaped end portion.

The first and second gate electrodes 124a and 124b, the first and second source electrodes 173a and 173b, and the first and second drain electrodes 175a and 175b form first and second thin film transistors Qa and Qb together with the first and second projections 154a and 154b of the semiconductor 151. The channels of the first and second thin film transistors Qa and Qb are formed at the first and second projections 154a and 154b between the first and second source electrodes 173a and 173b and the first and second drain electrodes 175a and 175b.

The data conductors 171, 175a and 175b are preferably formed with a refractory metal such as molybdenum, chromium, tantalum, and/or titanium, or alloys thereof, or may have a multi-layered structure with a refractory metal-based layer and a low resistance conductive layer. Examples of the multi-layered structure are a double-layered structure with a chromium or molybdenum (or alloy thereof)-based under layer and an aluminum (alloy)-based over layer, and a triple-layered structure with a molybdenum (alloy)-based under layer, an aluminum (alloy)-based middle layer, and a molybdenum (alloy)-based over layer. In addition, the data conductors 171, 175a, and 175b may be formed with various other metals or conductors. The lateral sides of the data conductors 171, 175a, and 175b are also preferably inclined with respect to the surface of the substrate 110 at 30 to 80°.

The ohmic contacts 161 and 165a only exist between the underlying semiconductor 151 and the overlying data conductors 171, 175a and 175b to lower the contact resistance therebetween. The linear-shaped semiconductor 151 is narrower than the data line 171 in most areas, but as explained earlier, is enlarged in width at the portion thereof that meets the gate line 121 and the storage electrode line 131 to make the surface profile smooth, thereby preventing the data line 171 from being cut. The semiconductor 151 has portions that are exposed between the source electrodes 173a and 173b and the drain electrodes 175a and 175b, and not covered by the data conductors 171, 175a and 175b.

A passivation layer 180 is formed on the data conductors 171, 175a and 175b and the exposed portions of the semiconductor 151. The passivation layer 180 has a lower layer portion 180p based on an inorganic insulating material such as silicon nitride and silicon oxide, and an upper layer portion 180q based on an organic insulating material. The organic insulating material preferably has a dielectric constant of 4.0 or less, and photosensitivity. The passivation layer 180 may be formed with a single-layered structure based on an inorganic insulating material or an organic insulating material.

A plurality of contact holes 182 and 185b are formed at the passivation layer 180 such that they expose the end portion 179 of the data line 171 and the second drain electrode 175b, respectively. Opening portions 188 are formed at the upper passivation layer 180q such that they are placed over the coupling electrodes 177a and expose the lower passivation layer 180p. Contact holes 185a are formed at the lower passivation layer 180p such that they are placed within the opening portions 188 and expose the coupling electrodes 177a. A plurality of contact holes 181a and 181b are formed at the passivation layer 180 and the gate insulating layer 140 such that they expose the end portions 129a and 129b of the gate lines 121a and 121b.

The contact holes 181a, 181b, 182, 185a and 185b and the opening portion 188 have a gently inclined sidewall. Particularly, the lateral sides of the contact holes 181a, 181b, 182, 185a and 185b and the opening portion 188 formed at the upper passivation layer 180q are inclined with respect to a surface of the substrate 110, preferably at 30 to 80°. In addition, the boundary of the opening portion 188 is preferably placed within the boundary of the coupling electrode 177a.

A plurality of pixel electrodes 191, a plurality of shielding electrodes 88, and a plurality of contact assistants 81a, 81b and 82 are formed on the passivation layer 180 with a transparent conductive material such as ITO and/or IZO, or a reflective metallic material such as aluminum, silver, chromium, and/or alloys thereof. The respective pixel electrodes 191 are shaped roughly with a rectangle edge-cut at left-side corners, and the edge-cut oblique sides are angled against the gate lines 121a and 121b at about 45°.

The respective pixel electrodes 191 have a pair of first and second sub-pixel electrodes 191a and 191b separated from each other while interposing a gap 92. The gap 92 has upper and lower inclined portions extended from the right side of the pixel electrode 191 toward the left side thereof, and a vertical portion interconnecting the inclined portions. The upper and lower inclined portions of the gap 92 are angled against the gate lines 121a and 121b at 45° while proceeding perpendicularly to each other.

Accordingly, the second sub-pixel electrode 191b is substantially shaped as an isosceles trapezoid rotated by about 90°, and the first sub-pixel electrode 191a has a pair of trapezoid-shaped portions facing the oblique sides of the second sub-pixel electrode 190b and rotated by about 90°, and a vertical portion facing the left side of the second sub-pixel electrode 190b. The second sub-pixel electrode 191b has a cutout 91 proceeding along the storage electrode line 131, and is bisected into upper and lower halves by way of the cutout 91. The cutout 91 has an entrance at the right side of the second sub-pixel electrode 191b, and the entrance of the cutout 91 has a pair of oblique sides proceeding substantially parallel to the upper and lower inclined portions of the gap 92. The gap 92 and the cutout 91 are in inversion symmetry with the storage electrode line 131.

The number of cutouts or regions may be varied depending upon the design factors such as the size of the pixel electrode 191, the length ratio of the horizontal side of the pixel electrode 191 to the vertical side thereof, and the kind and characteristics of the liquid crystal layer 3. For explanatory convenience, the gap 92 will be referred to hereinafter as a cutout.

The first sub-pixel electrode 191a is connected to the coupling electrode 177a that is connected to the first drain electrode 175a through the contact hole 185a, and the second sub-pixel electrode 191b is connected to the second drain electrode 175b through the contact hole 185b. The first and second sub-pixel electrodes 191a and 191b and a common electrode 270 of the common electrode panel 200 form first and second liquid crystal capacitors C_{Lca} and C_{LCb} to sustain the voltages applied thereto even after the thin film transistors Qa and Qb turn off. The respective liquid crystal capacitors C_{Lca} and C_{LCb} use the liquid crystal layer 3 as a dielectric.

The first sub-pixel electrode 191a and the coupling electrode 177a connected thereto and the first drain electrode 175a overlap the storage electrode line 131, including the storage electrode 137, while interposing the gate insulating layer 140 to form a storage capacitor C_{STa}, which reinforces the voltage storage capacity of the first liquid crystal capacitor C_{LCa}. The second sub-pixel electrode 191b overlaps the coupling electrode 177a at the cutout 188 while interposing the lower passivation layer 180p to form a connection capacitor Ccp.

As the storage capacitor and the connection capacitor share the same space, the areas of the two capacitors are relatively small. Accordingly, the aperture ratio is high compared to the case where the two capacitors are placed at different spaces. In addition, as the coupling electrode 177a and the second sub-pixel electrode 191b overlap each other while interposing only the thin lower passivation layer 180p, the connection capacitance is obtained sufficiently.

As the second sub-pixel electrode 191b overlaps the first gate line 121a while the first sub-pixel electrode 191a overlaps the first and second gate lines 121a and 121b, the aperture ratio increases. The first gate line 121a proceeds around the center of the upper half of the pixel electrode 191.

The shielding electrode 88 receives a common voltage, and extends along the data line 171 while completely covering the latter. The shielding electrode 88 shields the electromagnetic interference between the data line 171 and the pixel electrode 191 and between the data line 171 and the common electrode 270, thereby decreasing the voltage distortion of the pixel electrode 191 and the signal delay of the data voltage flowing along the data line 171.

The contact assistants 81a, 81b, and 82 are connected to the end portions 129a and 129b of the gate lines 121a and 121b and the end portion 179 of the data line 171 through the contact holes 181a, 181b, and 182, respectively. The contact assistants 81a, 81b, and 82 serve to reinforce the adhesion of the end portions 129a and 129b of the gate lines 121a and 121b and the end portion 179 of the data line 171 to external devices while protecting them.

The common electrode panel 200 will now be explained with reference to FIGS. 5 to 7B. A light blocking member 220 is formed on an insulating substrate 210 made with transparent glass or plastic. The light blocking member 220 is called a black matrix, and blocks the leakage of light. The light blocking member 220 faces the pixel electrodes 190 and has a plurality of opening portions, which have nearly the same shape as the pixel electrodes 190. However, the light blocking member 220 may be formed with portions corresponding to the gate and data lines 121 and 171, and portions corresponding to the thin film transistors.

A plurality of color filters 230 are formed on the substrate 210, and are mostly placed within the area surrounded by the light blocking member 230. The color filters 230 may longitudinally extend along the pixel electrode 190 in the vertical direction, and each color filter 230 may express one of the primary colors of red, green and blue.

An overcoat 250 is formed on the color filter 230 and the light blocking member 220 with an (organic) insulating material to prevent the color filter 230 from being exposed to the outside, and to provide a flattened surface. A common electrode 270 is formed on the overcoat 250 with a transparent conductor such as ITO and IZO. The common electrode 270 has sets of cutouts 71, 72a, and 72b.

A set of the cutouts 71, 72a and 72b face one pixel electrode 191, and include a central cutout 71, a lower cutout 72a and an upper cutout 72b. The respective cutouts 71, 72a and 72b are placed between the neighboring cutouts 91 and 92 of the pixel electrode 191 or between the cutouts 91 and 92 and the edge-cut oblique sides of the pixel electrode 191. In addition, the respective cutouts 71, 72a and 72b have at least one inclined portion proceeding parallel to the upper or lower inclined portion of the gap 94 of the pixel electrode 191, and are in inversion symmetry with the storage electrode line 131.

The lower and the upper cutouts 72a and 72b have an inclined portion and a pair of horizontal and vertical portions, respectively. The inclined portion proceeds from the left side of the pixel electrode 191 toward the top or the bottom side. The horizontal and the vertical portions proceed from the respective ends of the inclined portion along the sides of the pixel electrode 191 while overlapping those sides and obtuse-angled against the inclined portion.

The central cutout 71 has a horizontal center portion, a pair of inclined portions, and a pair of vertical end portions. The horizontal center portion is located around the left side of the pixel electrode 191, and proceeds along the storage electrode 137. The pair of inclined portions proceed from the end of the horizontal center portion toward the right side of the pixel electrode 191 while being oblique-angled against the horizontal center portion. The vertical end portions proceed from the ends of the inclined portions along the right side of the pixel electrode 191 while overlapping the right side and obtuse-angled against the inclined portions. The number of cutouts 71, 72a and 72b may also be varied depending upon design factors, and the light blocking member 220 may overlap the cutouts 71, 72a and 72b to thereby block the leakage of light around the cutouts 71, 72a and 72b.

Alignment layers 11 and 21 are formed on the inner surfaces of the panels 100 and 200. The alignment layers 11 and 21 may be vertical alignment layers. Polarizers 12 and 22 are attached to the outer surfaces of the panels 100 and 200. The polarizing axes of the two polarizers 12 and 22 proceed perpendicularly to each other, and one of the polarizing axes preferably proceeds parallel to the gate lines 121a and 121b. In the case of a reflection type of LCD, one of the two polarizers 12 and 22 may be omitted.

The LCD may include polarizers 12 and 22, a phase retardation film, display panels 100 and 200, and a backlight unit for illuminating light to the liquid crystal layer 3. The liquid crystal layer 3 has negative dielectric anisotropy, and the liquid crystal molecules of the liquid crystal layer 3 are aligned such that the directors thereof proceed perpendicularly to the surfaces of the two panels when there is no application of an electric field. Accordingly, the incident light does not pass the polarizers 12 and 22 proceeding perpendicularly to each other, and is intercepted thereby.

The display operation of the LCD will be now specifically explained with reference to FIGS. 1A to 2. The signal controller 600 receives input image signals R, G and B and input control signals for controlling the displaying thereof from an external graphic controller, such as vertical synchronization signals Vsync, horizontal synchronization signals Hsync, main clock signals MCLK, and data enable signals DE. The signal controller 600 suitably processes the image signals R, G and B pursuant to the operation conditions of the liquid crystal panel assembly 300, based on the input image signals R, G and B and the input control signals, and generates gate control signals CONT1 and data control signals CONT2. The signal controller 600 transmits the gate control signals CONT1 to the gate driver 400, and the data control signals CONT2 and the processed image signals DAT to the data driver 500.

The gate control signals CONT1 include scanning start signals STV for instructing to start the scanning, and at least one clock signal for controlling the output time of the gate on voltage Von. The gate control signals CONT1 may further include output enable signals OE for defining the duration time of the gate on voltage Von.

The data control signals CONT2 include horizontal synchronization start signals STH for informing of the data transmission to a group of pixels PX, load signals LOAD for applying the relevant data voltages to the data lines D1-Dm, and data clock signals HCLK. The data control signals CONT2 may include reverse signals RVS for inverting the polarity of the data voltage with respect to the common voltage Vcom (referred to hereinafter as “the polarity of the data voltage”).

The data driver 500 receives image data DAT for a group of sub-pixels PXa and Pxb in accordance with the data control signals CONT2 from the signal controller 600, and selects one set of gray voltages from the two sets of gray voltages from the gray voltage generator 800. The data driver 500 further selects the gray voltages corresponding to the respective image data DAT from the selected set of gray voltages, and suitably converts the image data DAT into data voltages to transmit them to the relevant data lines D1-Dm.

Alternatively, a separate external selection circuit may select one set of gray voltages from the two sets of gray voltages, and transmit them to the data driver 500. In addition, the gray voltage generator 800 may provide a reference voltage that is varied in value, and the data driver 500 may divide the reference voltage to make gray voltages.

The gate driver 400 applies the gate on voltages Von to the gate lines Gla-Gnb in accordance with the gate control signals CONT1 from the signal controller 600 to turn on the switching elements Qa and Ob connected to the gate lines G1a-Gnb. Accordingly, the data voltages applied to the data lines D1-Dm are applied to the relevant sub-pixels PXa and PXb via the turned-on switching elements Qa and Qb.

Referring to FIG. 2, a common voltage Vcom is applied to the storage electrode line 131. Here, the capacitors C_{LCa}, C_{STa}, C_{LCb} and Ccp and the static capacitances thereof are indicated by like reference symbols, and the initial voltages of the first and second liquid crystal capacitors C_{LCa} and C_{LCb} are indicated by Va0 and Vb0.

When the gate on voltage Von is applied to the first gate line 121a, the first switching element Qa turns on, and a data voltage is applied to the first sub-pixel electrode 191a. When the voltage of the first liquid crystal capacitor C_{LCa} is indicated by Va1, the voltage of the second liquid crystal capacitor C_{LCb} becomes Vb1=Vb0+[Va1−Va0]×[Ccp/(Ccp+C_{LCb})], by way of the voltage distribution law. When data voltages with the same polarity are applied to the two sub-pixel electrodes 191a and 191b, the second liquid crystal capacitor C_{LCb} is precharged by the connection capacitor Ccp.

When the gate on voltage is applied to the second gate line 121b, the second switching element Qb turns on, and the data voltage is applied to the second sub-pixel electrode 191b. When the voltage of the second liquid crystal capacitor C_{LCb} is indicated by Vb2, the voltage of the first liquid crystal capacitor C_{Lca} is determined by the connection capacitor Ccp as follows: Va2=Va1+(Vb2−Vb1)×[Ccp/(Ccp+C_{LCa}+C_{STa})], ΔVa=Va2−Va1=(Vb2−Vb1)×[Ccp/(CCp+C_{Lca}+C_{STa})]. When the data voltages with the same polarity are applied to the two sub-pixel electrodes 191a and 191b, the voltage of the first liquid crystal capacitor C_{LCa} is charged up by the value of ΔVa. This relation is sustained even when the voltage of the storage electrode line 131 is not the common voltage Vcom. Accordingly, effective driving may be made even with a lower voltage.

When the data voltage applied to the first sub-pixel electrode 191a is differentiated from the data voltage applied to the second sub-pixel electrode 191b, the voltage heightening degree of the first liquid crystal capacitor C_{LCa} and the ratio of the voltage Va of the first liquid crystal capacitor C_{Lca} to the voltage Vb of the second liquid crystal capacitor C_{LCb} may be controlled. In addition, the static capacitance Ccp of the connection capacitor Ccp may be controlled by varying the overlapping area and distance between the second sub-pixel electrode 191b and the coupling electrode 177a.

When a potential difference is made between both ends of the first and second liquid crystal capacitors C_{LCa} and C_{LCb}, an electric field is formed at the liquid crystal layer 3 nearly vertical to the surfaces of the panels 100 and 200. The pixel electrode 190 and the common electrode 270 will be referred to hereinafter as the “field generating electrodes.” The liquid crystal molecules of the liquid crystal layer 3 are inclined in response to the electric field such that the directions thereof proceed perpendicularly to the direction of the electric field, and the polarization of the light incident upon the liquid crystal layer 3 is varied depending upon the inclination degree of the liquid crystal molecules. The polarization variation makes the light transmittance varied due to the polarizers 12 and 22, thereby displaying the desired images.

The inclination angle of the liquid crystal molecules is varied depending upon the intensity of the electric field. In this embodiment, as the voltage Va of the first liquid crystal capacitor C_{LCa} is greater than the voltage Vb of the second liquid crystal capacitor C_{LCb} due to the connection capacitor, the inclination angle of the liquid crystal molecules at the first sub-pixel Xa differs from that at the second sub-pixels Xb, so the two sub-pixels Xa and Xb are differentiated in luminance from each other. Accordingly, when the voltage Va of the first liquid crystal capacitor C_{LCa} and the voltage Vb of the second liquid crystal capacitor C_{LCb} are properly controlled to be adapted to each other, the lateral-sided image is maximally approximated to the front-sided image, thereby enhancing the lateral side visibility.

The inclination of the liquid crystal molecules is determined by the horizontal component of the electric field that is due to the deformation of the electric field by way of the cutouts 71-72b, 91 and 92 of the field generating electrodes 191 and 270 and the oblique sides of the pixel electrode 191. The horizontal component of the electric field proceeds perpendicular to the sides of the cutouts 71-72b, 91 and 92 and the sides of the pixel electrode 191. As shown in FIG. 4, a set of the cutouts 71-72b, 91 and 92 partition the pixel electrode 191 into a plurality of sub-areas each with two inclined major edges. As the liquid crystal molecules over the respective sub-regions are inclined vertical to the major edge, the inclination is made in four directions. When the inclination directions of the liquid crystal molecules are diversified, the reference viewing angle of the LCD becomes widened.

The shape and arrangement of the cutouts 91, 92, and 71-72b for determining the inclination directions of the liquid crystal molecules may be varied, and at least one of the cutouts 91, 92, and 71-72b may be replaced by a protrusion or a depression. The protrusion may be formed with an inorganic material or an organic material, and be placed above or below the field generating electrodes 191 and 270.

The data driver 500 and the gate driver 400 repeat the same operation while taking a ½ horizontal cycle or ½H (a cycle of horizontal synchronization signals Hsync) as a unit. In this way, the gate on voltage Von is sequentially applied to all the gate lines G1-G2n for one frame such that the data voltage is applied to all the pixels. When one frame is terminated, the next frame starts, and the reverse signals RVS applied to the data driver 500 are controlled such that the polarity of the data voltage applied to the respective pixels is opposite to that in the previous frame (the “frame inversion”).

Meanwhile, as the same common voltage is applied to the common electrode 270 and the shielding electrode 88, no electric fields exist between the two electrodes. Accordingly, the liquid crystal molecules disposed between the common electrode 270 and the shielding electrode 88 sustain the initial alignment state so that the light incident thereto does not pass therethrough, but is intercepted.

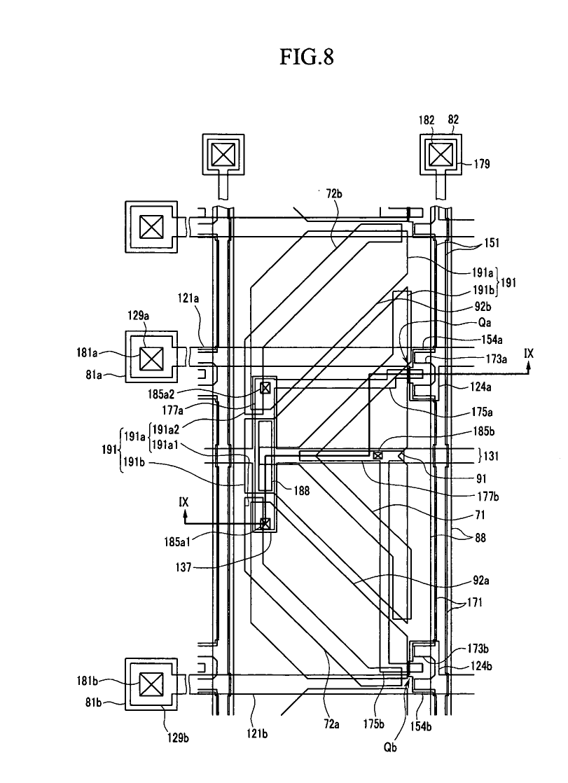

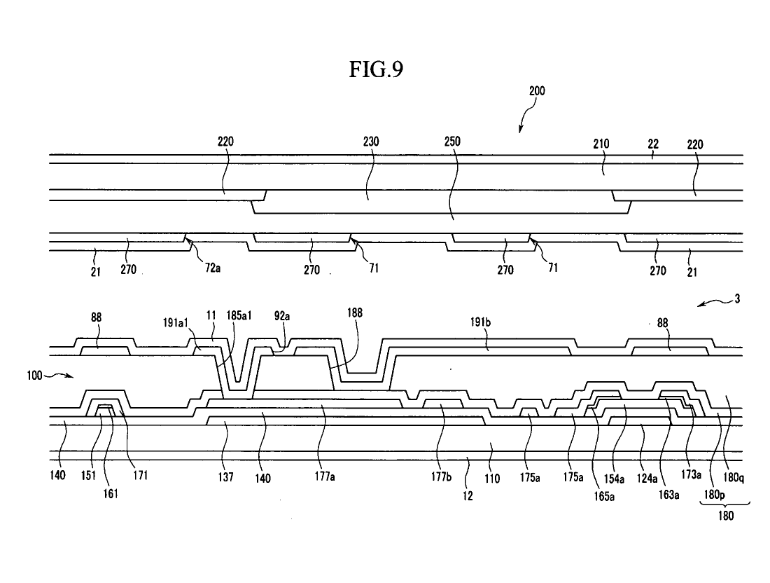

A liquid crystal panel assembly according to another embodiment of the present disclosure will be now specifically explained with reference to FIGS. 8 and 9. FIG. 8 is a plan view of a liquid crystal panel assembly according to another embodiment of the present disclosure, and FIG. 9 is a cross-sectional view of the liquid crystal panel assembly taken along the IX-IX line of FIG. 8.

As shown in FIGS. 8 and 9, the liquid crystal panel assembly according to the present embodiment includes a thin film transistor array panel 100, a common electrode panel 200, and a liquid crystal layer 3 disposed between the two panels 100 and 200. The layered structure of the liquid crystal panel assembly according to the present embodiment is nearly the same as that of the liquid crystal panel assembly shown in FIGS. 4 to 7B.

With the thin film transistor array panel 100, gate conductors are formed on an insulating substrate 110, and a gate insulating layer 140 is formed thereon. The gate conductors include a plurality of first and second gate lines 121a and 121b with first and second gate electrodes 124a and 124b and end portions 129a and 129b, and a plurality of storage electrode lines 131 with storage electrodes 137. A plurality of linear-shaped semiconductors 151 with projections 154a and 154b are formed on the gate insulating layer 140, and a plurality of linear-shaped and island-shaped ohmic contacts 161 and 165a with projections 163a are formed thereon. Data conductors are formed on the ohmic contacts 161 and 165a and the gate insulating layer 140. The data conductors include a plurality of data lines 171 with first and second source electrodes 173a and 173b and end portions 179, and a plurality of first and second drain electrodes 175a and 175b. A passivation layer 180 with a lower layer portion 180p and an upper layer portion 180q is formed on the data conductors 171, 175a, 175b and the exposed portions of the semiconductors 151. A plurality of pixel electrodes 191, a plurality of shielding electrodes 88, and a plurality of contact assistants 81a, 81b, and 82 are formed on the passivation layer 180. The respective pixel electrodes 191 have lower, upper, and middle sub-pixel electrodes 191a1, 191a2, and 191b partitioned by gaps 92a and 92b, respectively. An alignment layer 11 is finally formed thereon. With the common electrode panel 200, a light blocking member 220, a plurality of color filters 230, an overcoat 250, a common electrode 270 with cutouts 71-72b, and an alignment layer 21 are formed on an insulating substrate 210.

However, unlike with the liquid crystal panel assembly shown in FIGS. 4 to 7B, the storage electrode 137 extends around the left side of the pixel electrode 191 upwards and downwards. The first drain electrode 175a has a bar-shaped end portion, and a wide area portion (a coupling electrode) 177a extended from the bar-shaped end portion and overlapping the storage electrode 137. The second drain electrode 175b has a bar-shaped end portion, and a wide area portion 177b extended from the bar-shaped end portion up to the storage electrode line 131 and overlapping the storage electrode line 131 to thereby form a storage capacitor.

A plurality of contact holes 182, 185a1, 185a2 and 185b are formed at the passivation layer 180 to expose the end portion 179 of the data line 171, the lower and upper end portions of the coupling electrode 177a, and the wide area portion of the second drain electrode 175b, respectively. A plurality of contact holes 181a and 181b are formed at the passivation layer 180 and the gate insulating layer 140 to expose the end portions 129a and 129b of the gate lines 121a and 121b. Opening portions 188 are formed at the upper passivation layer 180q to expose the lower passivation layer 180p. The opening portions 188 are placed over the coupling electrode 177a and between the first and second contact holes 185a1 and 185a2, and the boundary of the opening portion 188 is placed within the boundary of the coupling electrode 177a.

In addition, the pixel electrode 191 is partitioned into lower and upper sub-pixel electrodes 191a1 and 191a2 (collectively called the first sub-pixel electrode 191a) and a middle sub-pixel electrode 191b (called the second sub-pixel electrode) by way of lower and upper gaps 92a and 92b. The lower and upper gaps 92a and 92b include an inclined portion gently extended from the left side of the pixel electrode 191 toward the right side thereof, and a short horizontal portion connected to the left-side end of the inclined portion. Accordingly, the middle sub-pixel electrode 191b is substantially shaped as an isosceles trapezoid rotated by roughly 90°, and the lower and upper sub-pixel electrodes 191a1 and 191a2 are substantially shaped as a right triangle rotated by roughly 90° where the right-angled portion is edge-cut. The lower and upper gaps 92a and 92b are angled against the gate line 121 at about 45° while proceeding perpendicularly to each other. The middle sub-pixel electrode 191b has a funnel-shaped and shortly-inclined entrance proceeding substantially parallel to the gaps 92a and 92b.

The lower and upper sub-pixel electrodes 191a1, 191a2, and 191b are connected to the first drain electrode 175a through the relevant contact holes 185a1 and 185a2, and the middle sub-pixel electrode 191b is connected to the second drain electrode 175b through the contact hole 185b. In addition, the second sub-pixel electrode 191b overlaps the coupling electrode 177a through the opening portion 188 to thereby form a connection capacitor.

The storage electrode 137 and the coupling electrode 177a overlap each other to form a storage capacitor, and the second sub-pixel electrode 191b overlaps the coupling electrode 177a while interposing the lower passivation layer 181p to form a connection capacitor. As the storage capacitor and the connection capacitor occupy the same space, the aperture ratio obtained is sufficient. In addition, this structure exerts the precharging and the charging up effects between the two sub-pixel electrodes 191a and 191b so that the driving voltage can be used effectively. Many features of the liquid crystal panel assembly shown in FIGS. 4 to 7B may be similarly applied to the liquid crystal panel assembly shown in FIGS. 8 and 9.

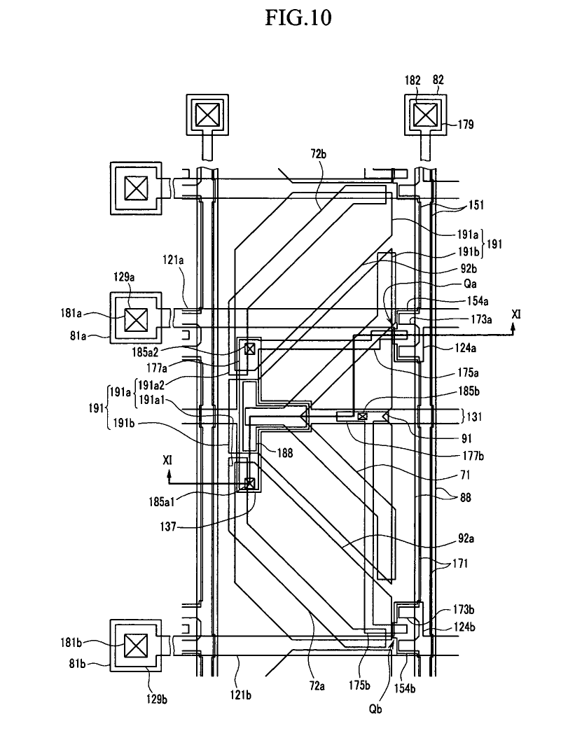

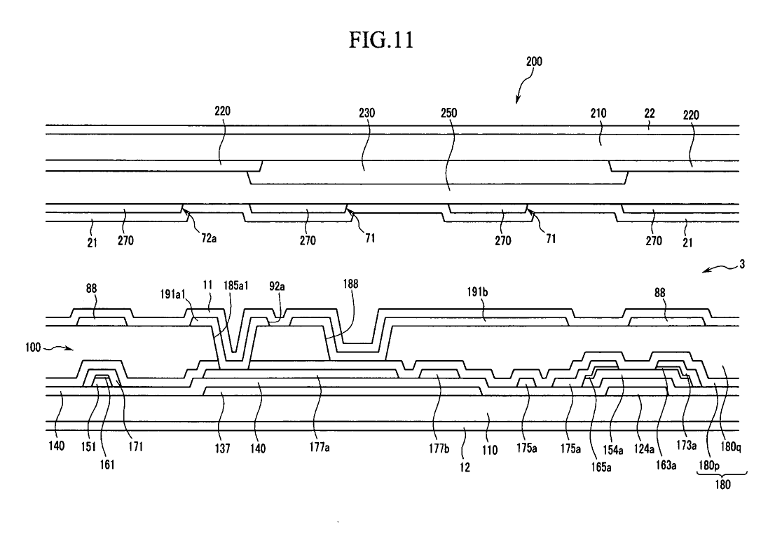

A liquid crystal panel assembly according to another embodiment of the present disclosure will be now specifically explained with reference to FIGS. 10 and 11. FIG. 10 is a plan view of a liquid crystal panel assembly according to another embodiment of the present disclosure, and FIG. 11 is a cross-sectional view of the liquid crystal panel assembly taken along the XI-XI line of FIG. 10.

As shown in FIGS. 10 and 11, the liquid crystal panel assembly according to the present embodiment includes a thin film transistor array panel 100, a common electrode panel 200, and a liquid crystal layer 3 disposed between the two panels 100 and 200. The layered structure of the liquid crystal panel assembly according to the present embodiment is nearly the same as that of the liquid crystal panel assembly shown in FIGS. 8 and 9.

With the thin film transistor array panel 100, gate conductors are formed on an insulating substrate 110, and a gate insulating layer 140 is formed thereon. The gate conductors include a plurality of first and second gate lines 121a and 121b with first and second gate electrodes 124a and 124b and end portions 129a and 129b, and a plurality of storage electrode lines 131 with storage electrodes 137. A plurality of linear-shaped semiconductors 151 with projections 154a and 154b are formed on the gate insulating layer 140, and a plurality of linear-shaped and island-shaped ohmic contacts 161 and 165a with projections 163a are formed thereon. Data conductors are formed on the ohmic contacts 161 and 165a and the gate insulating layer 140. The data conductors include a plurality of data lines 171 with first and second source electrodes 173a and 173b and end portions 179, and a plurality of first and second drain electrodes 175a and 175b with coupling electrodes 177a and wide area portions 177b. A passivation layer 180 with a lower layer portion 180p and an upper layer portion 180q is formed on the data conductors 171, 175a and 175b, and on the exposed portions of the semiconductors 151. A plurality of contact holes 181a, 181b, 182, 185a1, 185a2 and 185b and opening portions 188 are formed at the passivation layer 180 and the gate insulating layer 140. A plurality of pixel electrodes 191, a plurality of shielding electrodes 88, and a plurality of contact assistants 81a, 81b, and 82 are formed on the passivation layer 180. The respective pixel electrodes 191 have lower, upper, and middle sub-pixel electrodes 191a1, 191a2, and 191b partitioned by gaps 92a and 92b, respectively. An alignment layer 11 is finally formed thereon.

Unlike with the liquid crystal panel assembly shown in FIGS. 8 and 9, with the liquid crystal panel assembly according to the present embodiment, the storage electrode 137 is formed in the shape of a capital letter T laid laterally with a vertical portion placed close to the left side of the pixel electrode 191, and a horizontal portion extended along the storage electrode line 131. The coupling electrode 177a is similar in shape to the storage electrode 137, and the wide area portion 177b of the second drain electrode 175b has a shorter horizontal length. The opening portion 188 of the upper passivation layer 180q further has a horizontal portion proceeding along the storage electrode line 131, and the boundary of the opening portion 188 is placed within the boundary of the first drain electrode 175a.

Accordingly, compared to the liquid crystal panel assembly shown in FIGS. 8 and 9, the storage capacitance of the storage capacitor C_{STa} and the connection capacitance of the connection capacitor Ccp are further increased so that the voltage of the first sub-pixel electrode 191a is significantly heightened. Many features of the liquid crystal panel assembly shown in FIGS. 8 and 9 may be similarly applied to the liquid crystal panel assembly shown in FIGS. 10 and 11.

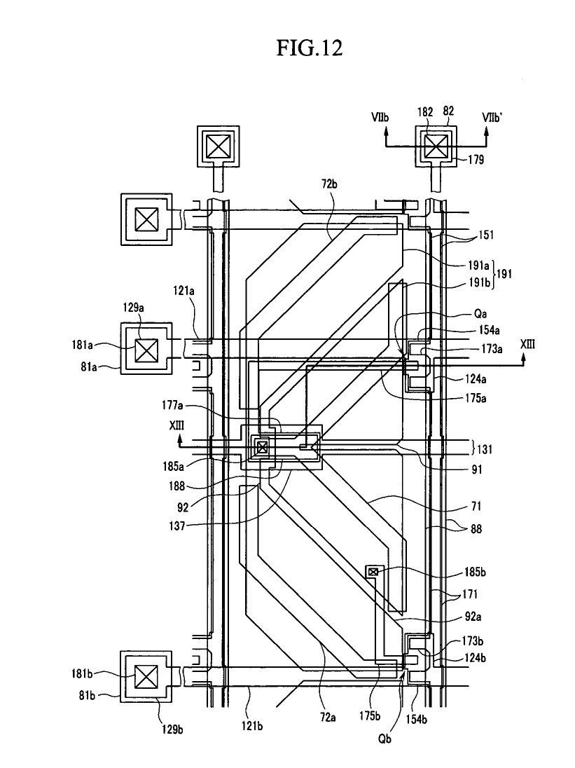

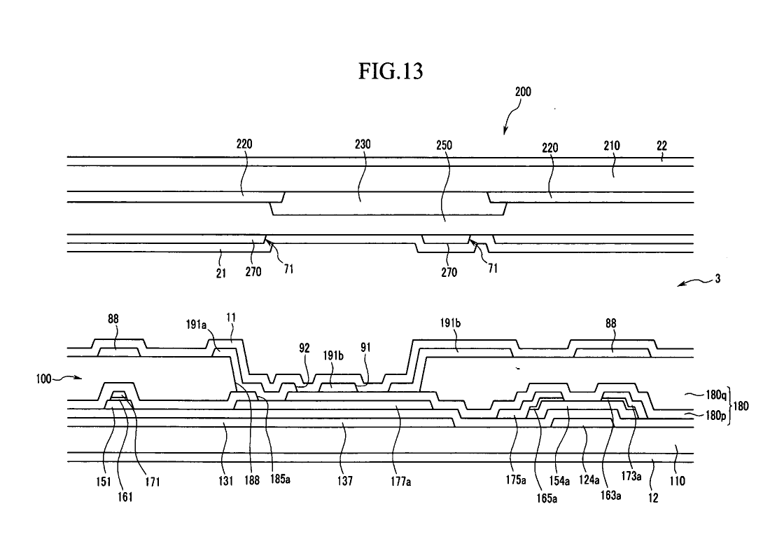

A liquid crystal panel assembly according to another embodiment of the present disclosure will be now specifically explained with reference to FIGS. 12 and 13. FIG. 12 is a plan view of a liquid crystal panel assembly according to another embodiment of the present disclosure, and FIG. 13 is a cross-sectional view of the liquid crystal panel assembly taken along the XIII-XIII line of FIG. 12.

As shown in FIGS. 12 and 13, the liquid crystal panel assembly according to the present embodiment includes a thin film transistor array panel 100, a common electrode panel 200, and a liquid crystal layer 3 disposed between the two panels 100 and 200. The layered structure of the liquid crystal panel assembly according to the present embodiment is nearly the same as that of the liquid crystal panel assembly shown in FIGS. 4 to 7B.

With the thin film transistor array panel 100, gate conductors are formed on an insulating substrate 110, and a gate insulating layer 140 is formed thereon. The gate conductors include a plurality of first and second gate lines 121a and 121b with first and second gate electrodes 124a and 124b and end portions 129a and 129b, and a plurality of storage electrode lines 131 with storage electrodes 137. A plurality of linear-shaped semiconductors 151 with projections 154a and 154b are formed on the gate insulating layer 140, and a plurality of linear-shaped and island-shaped ohmic contacts 161 and 165a with projections 163a are formed thereon. Data conductors are formed on the ohmic contacts 161 and 165a and the gate insulating layer 140. The data conductors include a plurality of data lines 171 with first and second source electrodes 173a and 173b and end portions 179, and a plurality of first and second drain electrodes 175a and 175b with coupling electrodes 177a. A passivation layer 180 with a lower layer portion 180p and an upper layer portion 180q is formed on the data conductors 171, 175a and 175b, and on the exposed portions of the semiconductors 151. A plurality of contact holes 181a, 181b, 182, 185a and 185b, and opening portions 188, are formed at the passivation layer 180 and the gate insulating layer 140. A plurality of pixel electrodes 191, a plurality of shielding electrodes 88, and a plurality of contact assistants 81a, 81b, and 82 are formed on the passivation layer 180. The respective pixel electrodes 191 have first and second sub-pixel electrodes 191a and 191b partitioned by a gap 92. An alignment layer 11 is finally formed thereon.

With the common electrode panel 200, a light blocking member 220, a plurality of color filters 230, an overcoat 250, a common electrode 270 with cutouts 71-72b, and an alignment layer 21 are formed on an insulating substrate 210. However, unlike with the liquid crystal panel assembly shown in FIGS. 4 to 7B, the storage electrode 137 extends from the left side of the pixel electrode 191 only up to the center thereof. The first drain electrode 175a has a bar-shaped end portion, and a wide area portion (a coupling electrode) 177a extended from the bar-shaped end portion toward the left side of the pixel electrode 191 and then extended downwards such that it overlaps the storage electrode 137. The boundary of the opening portion 188 of the upper passivation layer 180q is also placed within the boundary of the coupling electrode 177a.

Consequently, the liquid crystal panel assembly shown in FIGS. 12 and 13 has a higher aperture ratio compared to the liquid crystal panel assembly shown in FIGS. 4 to 7B. Many features of the liquid crystal panel assembly shown in FIGS. 4 to 7B may be similarly applied to the liquid crystal panel assembly shown in FIGS. 12 and 13.

Meanwhile, with the liquid crystal panel assemblies shown in FIGS. 4 to 13, the coupling electrode 177a may be separated from the first drain electrode 175a. In this case, the first drain electrode 175a is connected to the first sub-pixel electrode 191a at another place, and the coupling electrode 177a is connected to the first sub-pixel electrode 191a.

In addition, the coupling electrode 177a might optionally not be a part of the first drain electrode 175, but rather it may a part of the second drain electrode 175b, or it may be connected to the second sub-pixel electrode 191b. In this case, the coupling electrode 177a overlaps the first sub-pixel electrode 191a.

As described above, with the structures according to the embodiments of the present disclosure, the voltages of the two sub-pixels can be correctly controlled to the desired degree, and one of the sub-pixel electrodes is charged up due to the connection capacitor between the two sub-pixel electrodes, thereby enhancing the visibility. Simultaneously, the storage capacitor and the connection capacitor at a sub-pixel overlap each other, thereby heightening the aperture ratio and the light transmittance.

While the present invention has been described in detail with reference to preferred embodiments, those of ordinary skill in the pertinent art will appreciate that various modifications and substitutions can be made thereto without departing from the spirit and scope of the present invention as set forth in the appended claims.

What is claimed is:

1. A thin film transistor array panel comprising:
a substrate;
a first signal line formed on the substrate;
second and third signal lines crossing the first signal line;
a first thin film transistor connected to the first and second signal lines;
a second thin film transistor connected to the first and third signal lines;
a pixel electrode comprising a first sub-pixel electrode connected to the first thin film transistor and a second sub-pixel electrode connected to the second thin film transistor;
a conductor connected to the first sub-pixel electrode or the first thin film transistor and overlapping the second sub-pixel electrode; and
a storage electrode overlapping the conductor.

2. The thin film transistor array panel of claim 1, wherein the storage electrode and the second sub-pixel electrode are disposed on both sides of the conductor.

3. The thin film transistor array panel of claim 2, further comprising a first insulating layer disposed between the storage electrode and the conductor, and a second insulating layer disposed between the conductor and the first and second sub-pixel electrodes.

4. The thin film transistor array panel of claim 3, wherein the second insulating layer comprises a lower layer portion formed of an inorganic insulating material and an upper layer portion formed of an organic insulating material, and the conductor and the second sub-pixel electrode overlap each other while interposing the lower layer portion of the second insulating layer.

5. The thin film transistor array panel of claim 1, wherein the first sub-pixel electrode comprises at least two portions separated from each other.

6. The thin film transistor array panel of claim 1, further comprising a shielding electrode overlapping the data line.

7. The thin film transistor array panel of claim 1, wherein the first and second sub-pixel electrodes receive voltages with the same polarity.

8. The thin film transistor array panel of claim 1, wherein the data voltages applied to the first and second sub-pixel electrodes have different magnitudes from each other.

9. The thin film transistor array panel of claim 1, wherein at least one of the first and second sub-pixel electrodes comprises a cutout.

10. The thin film transistor array panel of claim 5, wherein the first and second sub-pixel electrodes receive voltages with the same polarity.

11. The thin film transistor array panel of claim 5, wherein the data voltages applied to the first and second sub-pixel electrodes have different magnitudes from each other.

12. The thin film transistor array panel of claim 5, wherein at least one of the first and second sub-pixel electrodes comprises a cutout.

13. The thin film transistor array panel of claim 6, wherein the first and second sub-pixel electrodes receive voltages with the same polarity.

14. The thin film transistor array panel of claim 6, wherein the data voltages applied to the first and second sub-pixel electrodes have different magnitudes from each other.

15. The thin film transistor array panel of claim 6, wherein at least one of the first and second sub-pixel electrodes comprises a cutout.

16. A liquid crystal display comprising:
a substrate;
a first signal line formed on the substrate;
second and third signal lines crossing the first signal line;
a first thin film transistor connected to the first and second signal lines;
a second thin film transistor connected to the first and third signal lines;
a pixel electrode comprising a first sub-pixel electrode connected to the first thin film transistor and a second sub-pixel electrode connected to the second thin film transistor;
a conductor connected to the first sub-pixel electrode or the first thin film transistor and overlapping the second sub-pixel electrode; and
a storage electrode overlapping the conductor.

17. The liquid crystal display of claim 16, further comprising a common electrode facing the first and second sub-pixel electrodes.

18. The liquid crystal display of claim 17, wherein the common electrode and at least one of the first and second sub-pixel electrodes have cutouts arranged in an alternate manner.

19. The liquid crystal display of claim 18, wherein a gap between the first and second sub-pixel electrodes and the cutout of the common electrode are arranged in an alternate manner.

20. The liquid crystal display of claim 17, wherein at least one of the pixel electrode or common electrode is formed in the shape of a line or a bar.
